(19) United States
(12) Patent Application Publication
(10) Pub. No.: US 2012/0205707 A1
(43) Pub. Date: Aug. 16, 2012

(54) LIGHT-EMITTING DIODE PACKAGE

(75) Inventors: Yun-Li LI, Tainan City (TW); Po-Jen Su, Tainan City (TW)

(73) Assignee: Genesis Photonics Inc., Tainan City (TW)

(21) Appl. No.: 13/287,441

(22) Filed: Nov. 2, 2011

(30) Foreign Application Priority Data
Feb. 11, 2011 (TW) 100104601

(51) Int. Cl. H01L 33/62

(52) U.S. Cl. 257/99; 257/E33.066

(57) ABSTRACT

A light-emitting diode package includes: a frame unit, and at least one light-emitting diode chip including a chip body and a contact layer disposed between the chip body and the frame unit. One of the frame unit and the contact layer contains a magnetic material, and the other one of the frame unit and the contact layer contains a material capable of being magnetically attracted to the magnetic material.

### CROSS-REFERENCE TO RELATED APPLICATION

This application claims priority of Taiwanese application no. 100104601, filed on Feb. 11, 2011.

### BACKGROUND OF THE INVENTION

1. Field of the Invention

The present invention relates to a device package, more particularly to a light-emitting diode package.

2. Description of the Related Art

Referring to FIG. 1, a conventional surface mount type light-emitting diode package is shown to comprise a light-emitting diode chip 12, an adhesive 11, a frame unit 13, a sealing cup 101, alight-transmissive sealing resin 102, and gold wires 103. The manufacturing process of the conventional light-emitting diode package generally involves attaching the light-emitting diode chip 12 to the frame unit 13, for example, a lead frame, by means of the adhesive 11, for example, silver paste, and then performing a wire bonding process, a resin sealing process, and a cutting process.

More specifically, the adhesive 11 is first applied to a predetermined position on the frame unit 13 and then the light-emitting diode chip 12 is precisely placed on the adhesive 11 at the predetermined position before the adhesive 11 completely dries out. Thereafter, the adhesive 11 is sintered through a baking process in order to firmly attach the light-emitting diode chip 12 to the frame unit 13. Since the precise positioning of the light-emitting diode chip 12 and the baking process are required, the manufacturing process of the conventional light-emitting diode package is relatively complicated.

In addition, when the aforesaid light-emitting diode package formed by using the adhesive 11 is activated, the waste heat of the light-emitting diode chip 12 is conducted through the adhesive 11 and then dissipated from the light-emitting diode chip 12 via the frame unit 13. However, because the thermal conductivity coefficient of the adhesive 11 is generally low, the heat-dissipating effect is poor, thereby adversely affecting the service lifetime of the light-emitting diode package.

### SUMMARY OF THE INVENTION

Therefore, the object of the present invention is to provide a light-emitting diode package that can simplify the manufacturing process thereof and that can overcome the drawback of inferior heat dissipation.

Accordingly, a light-emitting diode package of the present invention comprises: a frame unit; and at least one light-emitting diode chip including a chip body and a contact layer disposed between the chip body and the frame unit. One of the frame unit and the contact layer contains a magnetic material, and the other one of the frame unit and the contact layer contains a material capable of being magnetically attracted to the magnetic material.

### BRIEF DESCRIPTION OF THE DRAWINGS

Other features and advantages of the present invention will become apparent in the following detailed description of the preferred embodiments with reference to the accompanying drawings, of which:

FIG. 1 is a partly schematic cross sectional view of a conventional light-emitting diode package;

FIG. 2 is a partly schematic cross sectional view of the first preferred embodiment of a light-emitting diode package according to the present invention;

FIG. 3 is a partly schematic cross sectional view of the second preferred embodiment of a light-emitting diode package according to the present invention;

FIG. 4 is a partly schematic cross sectional view of the third preferred embodiment of a light-emitting diode package according to the present invention; and

FIG. 5 is a partly schematic cross sectional view of the fourth preferred embodiment of a light-emitting diode package according to the present invention.

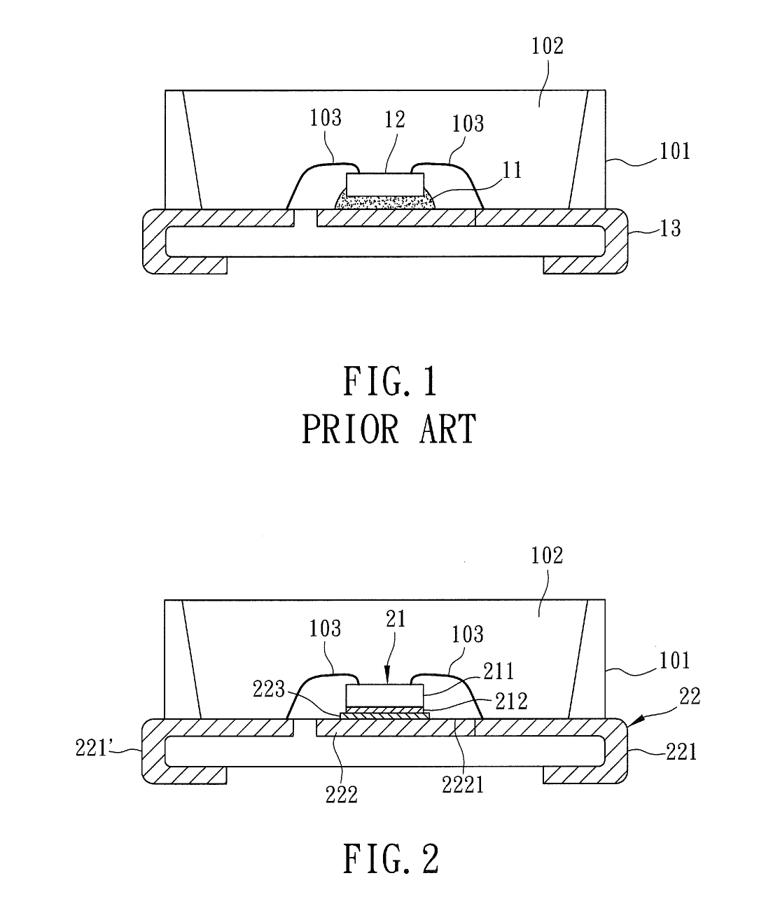

### DETAILED DESCRIPTION OF THE PREFERRED EMBODIMENTS

Before the present invention is described in greater detail, it should be noted that like components are assigned the same reference numerals throughout the following disclosure.

Referring to FIG. 2, the first preferred embodiment of a light-emitting diode package of the present invention comprises at least one light-emitting diode chip 21, a frame unit 22, a sealing cup 101, a light-transmissive sealing resin 102, and gold wires 103. In this embodiment, the light-emitting diode package is a surface mount type light-emitting diode package in which a single light-emitting diode chip 21 is mounted on the frame unit 22.

The light-emitting diode chip 21 includes a chip body 211 and a contact layer 212 disposed between the chip body 211 and the frame unit 22. The chip body 211 can emit light when electricity is supplied thereto. The chip body 211 includes, for example, n-cladding layer, p-cladding layer, an active layer, a transparent conductive layer which provides a uniformly lateral diffusion path for current, and electrodes for supplying electric power from an external circuit. The active layer can have homostructure, single heterostructure, double heterostructure, or multiple quantum wells.

In this invention, one of the frame unit 22 and the contact layer 212 contains a magnetic material, and the other one of the frame unit 22 and the contact layer 212 contains a material capable of being magnetically attracted to the magnetic material. In this embodiment, the frame unit 22 contains a magnetic material, and the contact layer 212 contains a material capable of being magnetically attracted to the magnetic material of the frame unit 22, so that the frame unit 22 can be attached to the contact layer 212 of the light-emitting diode chip 21 by virtue of the magnetic attractive force therebetween. In addition, the contact layer 212 is formed on the chip body 211, for example, an entire bottom face of the chip body 211, by means of a sputtering process, a vapor deposition process, or the like.

More specifically, the frame unit 22 includes: a chip pad 222 that is disposed to correspond in position to the light-emitting diode chip 21; a chip-attractive portion 223 formed on a top surface 2221 of the chip pad 222 ; and two leg portions 221, 221′ electrically coupled to the light-emitting diode chip 21. One of the leg portions 221, 221′ is in contact with the chip pad 222. In this embodiment, the chip-attractive portion 223 is made of the material capable of being magnetically attracted to the magnetic material of the frame unit 22 so that the chip-attractive portion 223 and the contact layer 212 can be magnetically attracted to each other.

The magnetic material can be formed by metal or ceramic material. Examples of the magnetic material may include iron or rare earth metals, for example, Nd, Nd—Fe—B, Sm—Co, Al—Ni—Co, and ceramics (for example, ferrite, Sr-based ferrite). The magnetic material may be a permanent magnet or a non-permanent magnet. The non-permanent magnet may be made of, for example, an electromagnetic material.

The material capable of being magnetically attracted to the magnetic material of the frame unit 22 may be a ferromagnetic material, for example, Fe, Ni, Co and alloys thereof. When the light-emitting diode chip 21 is desired to be attached to the frame unit 22, the light-emitting diode chip 21 is simply placed adjacent to the chip pad 222 to allow the contact layer 212 of the light-emitting diode chip 21 and the chip-attractive portion 223 of the frame unit 22 to attract magnetically to each other. Thus, the light-emitting diode chip 21 can be attached to the chip pad 222 without any precision positioning process. Preferably, the chip-attractive portion 223 and the chip pad 222 of the frame unit 22 are both made of a material having a thermal conductivity coefficient of not less than 20 w/m·K. More preferably, the frame unit 22 is made of a material having an overall thermal conductivity coefficient of not less than 20 w/m·K. When electricity is supplied to enable the light-emitting diode chip 21 to emit light, the waste heat generated from the light-emitting diode chip 21 is conducted through the chip-attractive portion 223, the chip pad 222, and the leg portions 221, 221′, and dissipated from the light-emitting diode chip 21 so as to further maintain stable operation of the light-emitting diode package.

According to the first embodiment of the light-emitting diode package of this invention, the contact layer 212 of the light-emitting diode chip 21 and the chip-attractive portion 223 of the frame unit 22 are magnetically attracted to each other. Therefore, the light-emitting diode chip 21 can be attached to the chip pad 222 of the frame unit 22 without any particular precise positioning process during the attaching process. Compared to the manufacturing process of the conventional light-emitting diode package which uses the adhesive to perform the attaching process, the process for manufacturing the light-emitting diode package of the present invention is simplified because the cost of the adhesive and the processes for applying and baking the adhesive and the equipments associated therewith are eliminated, thereby dramatically reducing manufacturing costs.

In addition, because there is no adhesive in the light-emitting diode package of the present invention, when electricity is supplied to enable the light-emitting diode chip 21 to emit light, the waste heat generated from the light-emitting diode chip 21 can be conducted more quickly through the chip-attractive portion 223, the chip pad 222, and the leg portions 221, 221′.

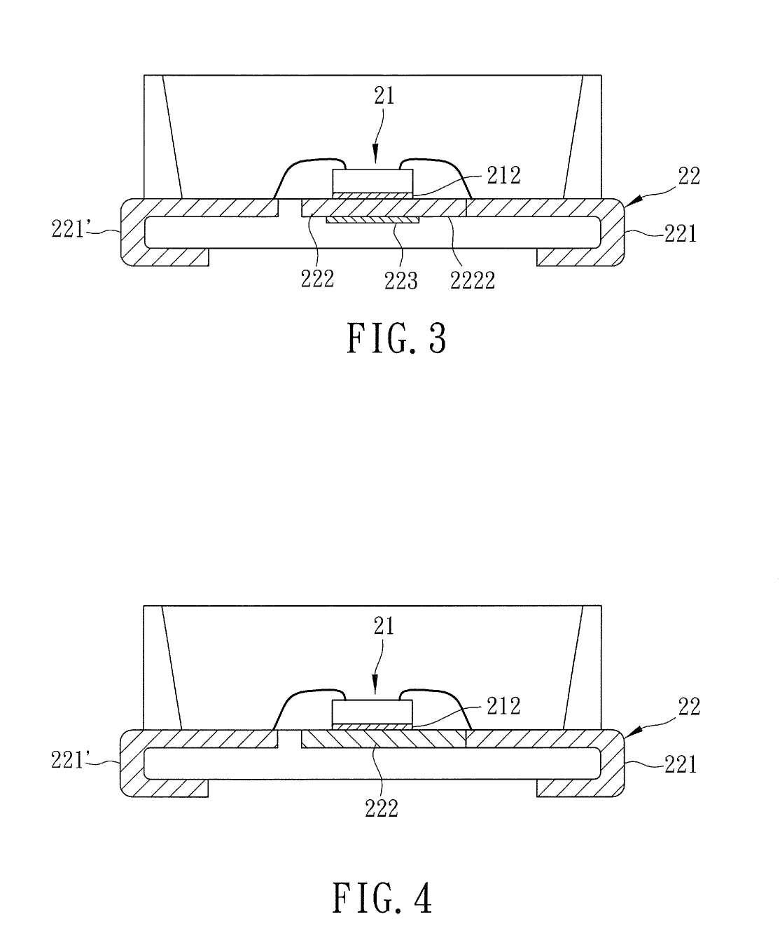

Referring to FIG. 3, the second preferred embodiment of a light-emitting diode package of the present invention is shown. The second preferred embodiment is similar to the first preferred embodiment except that the chip-attractive portion 223 is formed on a bottom surface 2222 of the chip pad 222 and is separated from the contact layer 212 by the chip pad 222. In this embodiment, the chip-attractive portion 223 and the contact layer 212 are magnetically attracted to each other to achieve the same effect as that achieved by the first preferred embodiment. Similarly, the light-emitting diode package of the second preferred embodiment is a surface mount type light-emitting diode package.

Referring to FIG. 4, the third preferred embodiment of a light-emitting diode package of the present invention is shown. The third preferred embodiment is similar to the first preferred embodiment except that the frame unit 22 includes: a chip pad 222 that is magnetically attracted to the contact layer 212; and two leg portions 221, 221′ electrically coupled to the light-emitting diode chip 21. One of the leg portions 221, 221′ is in contact with the chip pad 222. In this embodiment, the chip pad 222 and the contact layer 212 are magnetically attracted to each other, and thus, the chip-attractive portion 223 is dispensed with in this embodiment. Similarly, the light-emitting diode package of the third preferred embodiment is a surface mount type light-emitting diode package.

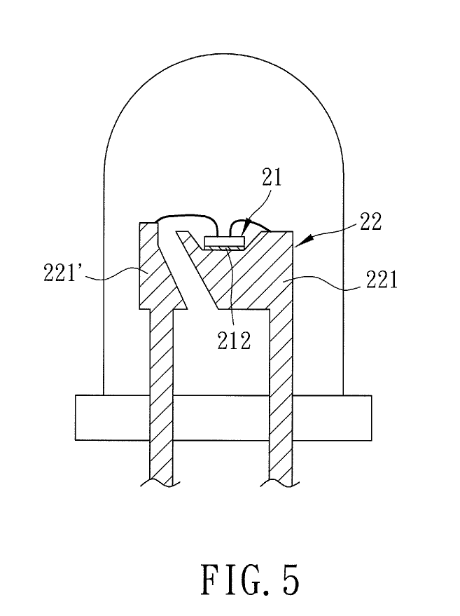

Referring to FIG. 5, the fourth preferred embodiment of a light-emitting diode package of the present invention is shown. The fourth preferred embodiment is similar to the first preferred embodiment except that the contact layer 212 contains a magnetic material and the frame unit 22 includes first and second leg portions 221, 221′ electrically coupled to the light-emitting diode chip 21. The first leg portion 221 is in contact with the contact layer 212 and is made of a material capable of being magnetically attracted to the magnetic material of the contact layer 212. In addition, the light-emitting diode package of the fourth preferred embodiment is a lamp type light-emitting diode package.

To sum up, since there is no adhesive in the light-emitting diode package of the present invention, when electricity is supplied to enable the light-emitting diode chip 21 to emit light, the waste heat generated from the light-emitting diode chip 21 can be dissipated more quickly through the frame unit 22 so as to further maintain stable operation of the light-emitting diode package. Moreover, costs relevant to the adhesive can be eliminated, thereby reducing manufacturing costs of the light-emitting diode package.

While the present invention has been described in connection with what are considered the most practical and preferred embodiments, it is understood that this invention is not limited to the disclosed embodiments but is intended to cover various arrangements included within the spirit and scope of the broadest interpretation so as to encompass all such modifications and equivalent arrangements.

What is claimed is:

1. A light-emitting diode package, comprising:
a frame unit; and
at least one light-emitting diode chip including a chip body and a contact layer disposed between said chip body and said frame unit;
wherein one of said frame unit and said contact layer contains a magnetic material, and the other one of said frame unit and said contact layer contains a material capable of being magnetically attracted to the magnetic material.

2. The light-emitting diode package of claim 1, wherein said frame unit contains the magnetic material, and said contact layer contains the material capable of being magnetically attracted to the magnetic material of said frame unit.

3. The light-emitting diode package of claim 1, wherein said frame unit includes:
a chip pad that is disposed to correspond in position to said light-emitting diode chip;
a chip-attractive portion formed on a top surface of said chip pad to connect to said contact layer, said chip-attractive portion and said contact layer being magnetically attracted to each other; and
two leg portions electrically coupled to said light-emitting diode chip, one of which being in contact with said chip pad.

4. The light-emitting diode package of claim 1, wherein said frame unit includes:
a chip pad that is disposed to correspond in position to said light-emitting diode chip;
a chip-attractive portion formed on a bottom surface of said chip pad and separated from said contact layer by said chip pad, said chip-attractive portion and said contact layer being magnetically attracted to each other; and
two leg portions electrically coupled to said light-emitting diode chip, one of which being in contact with said chip pad.

5. The light-emitting diode package of claim 3, wherein said chip-attractive portion is made of a material having a thermal conductivity coefficient of not less than 20 w/m·K.

6. The light-emitting diode package of claim 4, wherein said chip-attractive portion is made of a material having a thermal conductivity coefficient of not less than 20 w/m·K.

7. The light-emitting diode package of claim 1, wherein said frame unit includes:
a chip pad that is magnetically attracted to said contact layer; and
two leg portions electrically coupled to said light-emitting diode chip, one of which being in contact with said chip pad.

8. The light-emitting diode package of claim 7, wherein said chip pad is made of a material having a thermal conductivity coefficient of not less than 20 w/m.K.

9. The light-emitting diode package of claim 1, wherein said contact layer contains the magnetic material, said frame unit including first and second leg portions electrically coupled to said light-emitting diode chip, said first leg portion contacting said contact layer and being made of the material capable of being magnetically attracted to the magnetic material of said contact layer.

10. The light-emitting diode package of claim 9, wherein the material of said first leg portion of said frame unit has a thermal conductivity coefficient of not less than 20 w/m·K.
